(19) United States
(12) Patent Application Publication
(10) Pub. No.: US 2022/0270960 A1
(43) Pub. Date: Aug. 25, 2022

(54) Open-Cavity Package for Chip Sensor

(71) Applicant: Texas Instruments Incorporated, Dallas, TX (US)

(72) Inventors: Ernst Georg Muellner, Muenchen (DE); Michael Lueders, Freising (DE)

(21) Appl. No.: 17/363,200

(22) Filed: Jun. 30, 2021

Related U.S. Application Data
(60) Provisional application No. 63/152,375, filed on Feb. 23, 2021.

(51) Int. Cl. H01L 23/498; H01L 23/495; H01L 23/31; H01L 21/48; H01L 21/56

(52) U.S. Cl. CPC H01L 23/49838; H01L 23/49541; H01L 23/3157; H01L 21/4846; H01L 21/561

(57) ABSTRACT

In described examples, a device includes an interconnect substrate that has an aperture through the interconnect substrate. An integrated circuit (IC) die that has an on-chip element is mounted on the interconnect substrate with the on-chip element aligned with and facing the aperture. The IC die is over-molded with mold compound only on one side of the interconnect substrate so that the aperture remains free of mold compound to allow the on-chip element to have access to the environment.

### CROSS-REFERENCE TO RELATED APPLICATION

This application claims priority to U.S. Provisional Patent Application No. 63/152,375, entitled “OPEN-CAVITY ROUTABLE LEADFRAME (RLF) PACKAGES FOR CHIP SENSORS,” filed Feb. 23, 2021, the entirety of which is incorporated herein by reference.

### TECHNICAL FIELD

This relates to a package for an integrated circuit chip that has an open cavity to allow environmental access for a sensor on the chip.

### BACKGROUND

Integrated circuit (IC) chip sensors in which the sensor element is at the surface or within the bulk of the chip, such as humidity sensors, gas sensors, pH sensors, light sensors, MEMS (micro electromechanical) sensors, etc., require an opening in the package to allow the physical/environmental material to be measured to reach the sensor.

Techniques like film assisted molding (FAM) that can mold an open cavity in the package require a difficult and expensive setup to achieve a reasonably priced solution. Ceramic packages that provide an opening in the package have a prohibitive price tag for many applications.

### SUMMARY

In described examples, a device includes an interconnect substrate that has an aperture through the interconnect substrate. An integrated circuit (IC) die that has an on-chip element is mounted on the interconnect substrate with the on-chip element aligned with and facing the aperture. The IC die is over-molded with mold compound only on one side of the interconnect substrate so that the aperture remains free of mold compound to allow the on-chip element to have access to the environment.

### BRIEF DESCRIPTION OF THE DRAWINGS

FIG. 1 is an isometric view of an example device in which an interconnect substrate includes an aperture to expose an on-chip sensor to the environment.

FIG. 2 is a cross-sectional view of an example film assisted molding technique.

FIG. 3 is a cross-sectional view of an example device in which an interconnect substrate includes an aperture to expose an on-chip sensor.

FIG. 4 is a cross-sectional view of another example device in which an interconnect substrate includes an aperture to expose an on-chip sensor in a flip-chip configuration.

FIGS. 5A-5C are bottom views illustrating fabrication of an aperture in an example interconnect substrate.

FIGS. 6A-6K illustrate fabrication of an example interconnect substrate.

FIG. 7 is a bottom view of an example interconnect substrate with a sealing ring.

FIGS. 8A-8G illustrate assembly and encapsulation of an example device with an aperture to expose an on-chip sensor.

FIG. 9 is a cross sectional view of a strip of example interconnect substrates illustrating several encapsulated devices prior to singulation.

FIG. 10 is a schematic of an example device that includes an on-chip sensor

### DETAILED DESCRIPTION

In the drawings, like elements are denoted by like reference numerals for consistency.

Multilayer routable lead frame (RLF) interconnect substrate, also known as “molded interconnect substrate,” is a packaging technique that allows low-cost packages. There is no difficult or expensive tooling required to fabricate an RLF interconnect substrate which allows quick prototyping and easy creation of package variants. The multilayer capability offers flexibility in the pin-out of the encapsulated package.

RLF is an interconnect substrate that is fabricated using a series of additive process steps to form an interconnect substrate having one or more conductive layers that are patterned into routed leads and covered with insulating material. An integrated circuit (IC) die can be mounted on the interconnect substrate and then the RLF and IC die are encapsulated to form an IC device.

An example RLF interconnect substrate is configured to create an aperture that penetrates the interconnect substrate from one surface to an opposite surface. The aperture is formed before an IC die that includes a sensor element is attached to the interconnect substrate. After attaching the IC die with the sensor element exposed in the aperture, only the back side of the chip is over-molded. In this way, the sensor element is exposed to the environment while process steps such as etching directly on the sensor element surface are avoided.

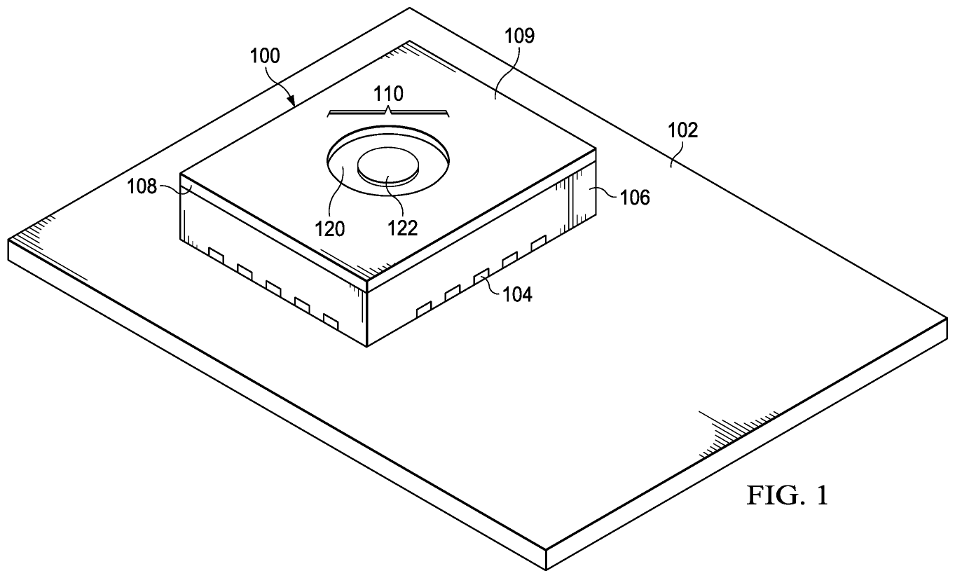

FIG. 1 is an isometric view of an example sensor device 100 having an aperture 110 to expose an on-chip sensor 122. Aperture 110 is formed through interconnect substrate 108 prior to attaching IC die 120 to interconnect substrate 108. Aperture 110 penetrates interconnect substrate 108 from surface 109 to an opposite surface (not visible in this figure) on which IC die 120 is mounted. In this example, a lead frame is coupled to interconnect substrate 108 to provide a set of package contacts as indicated at 104. Only the back side of IC 120 and interconnect substrate 108 are over-molded with mold compound 106 to form sensor device 100. Surface 109 of interconnect substrate 108 remains free of mold compound.

In this example, sensor device 100 is mounted on printed circuit board (PCB) 102 as part of a larger system. PCB 102 is fabricated using known or later developed PCB techniques. Sensor device 100 is coupled to bond pads and thereby to circuit traces within PCB 102 using known or later techniques, such a solder reflow. In another example, another type of system substrate may be used in place of PCB 102, such as a ceramic substrate, a flexible film substrate, etc.

In this example, aperture 110 is located on the top side of device 100 to allow sensor element 122 to be exposed to the environment after device 100 is mounted on a PCB or other type of system substrate.

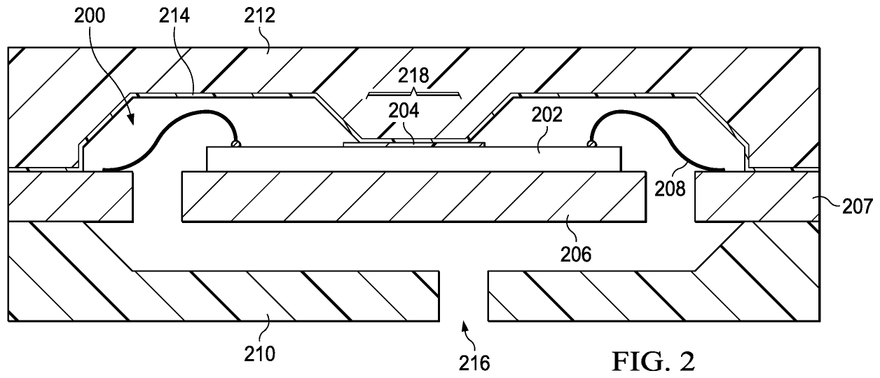

FIG. 2 is a cross-sectional view of an example film assisted molding technique. In this example, an IC die 202 that has an on-chip sensor element 204 is mounted on a lead frame die attach pad (DAP) 206 and coupled to leads 207 by bond wires 208. IC die 202 and DAP 206 are then over molded using a lower mold 210 and an upper mold 212 into which mold compound is injected through port 216 to fill a space 200 that surrounds IC die 202 and DAP 206 to form a packaged sensor device. In this example, a thin film 214 of non-stick ethylene tetrafluoroethylene (ETFE) is used as a mold release agent.

A portion 218 of upper mold 212 is configured to nearly touch sensor element 204. ETFE thin film 214 seals the remaining space between upper mold 218 and on-chip sensor 204. In this manner, an aperture is formed that allows on-chip sensor 204 to be exposed to the environment.

However, fabricating a sensor device using a FAM process requires a difficult and expensive setup to create the required upper and lower molds.

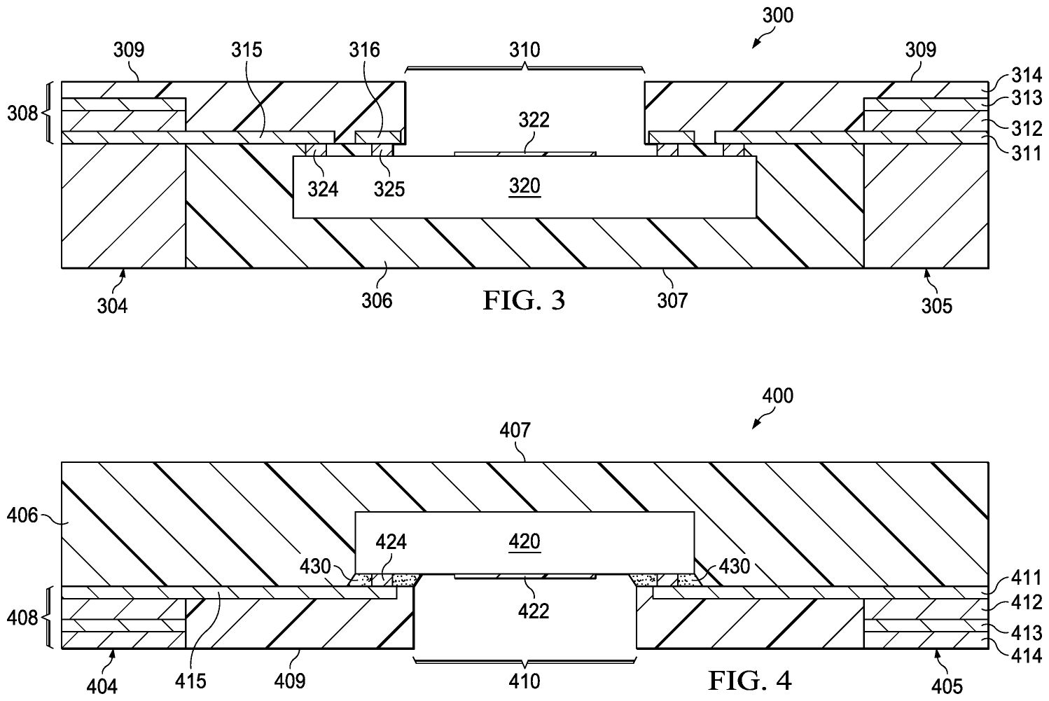

FIG. 3 is a cross-sectional view of an example device 300 in which an interconnect substrate 308 includes an aperture 310 to expose an on-chip sensor 322 located on IC die 320 to the environment. Example device 300 is similar to example device 100 (FIG. 1).

Interconnect substrate 308 includes several layers of conductive and insulating material in which the conductive layers are patterned to form interconnect lead lines. In this example, layer 311 and layer 313 are conductive layers that are patterned into lead lines and contact pads. For example, lead line 315 is representative of various lead lines in lead layer 311. Contact pad 316 is representative of various contact pads in lead layer 311. Vias are formed in via layer 312 to connect between lead lines in layer 311 and lead lines in layer 313. An insulating material 314 is placed between the lead lines to insulate them from each other. In this example, the insulating material is Ajinomoto™ Build-up Film (ABF). A process for fabricating interconnect substrate 308 will be described in more detail hereinbelow.

An aperture 310 is fabricated in interconnect substrate 308 that extends from the top surface of interconnect substrate 308 to the opposite bottom surface of interconnect substrate 308. The location of aperture 310 is selected to align with the position of sensor element 322 when IC die 320 is coupled to interconnect substrate 308.

In this example, IC die 320 has copper posts formed on each bond pad of IC die 320. Post 324 is representative of these copper posts. The copper posts are fabricated using a known or later developed technique for forming posts on a silicon die. IC die 320 is coupled to interconnect substrate by soldering the copper posts to respective lead lines; for example, copper post 324 is soldered to interconnect lead line 315 using a known or later developed die attach technique.

In this example, a continuous copper ring 325 that surrounds sensor 322 is fabricated on IC 320 along with the copper posts, such as copper post 324. Copper ring 325 is positioned to align with a copper ring 316 that is fabricated in layer 311 of interconnect substrate 308. Copper ring 325 is soldered to copper ring 316 at the same time the copper posts are soldered to the lead lines using a known or later developed die attach technique. In this manner, a seal is formed between the IC die in the perimeter region around sensor element 322 and the bottom surface of interconnect substrate 308. This seal prevents mold compound from entering aperture 310 when IC die 320 is over-molded with mold compound 306.

In this example, a lead frame has a set of lead frame contacts represented by lead frame contacts 304, 305. The lead frame contacts are coupled to interconnect substrate 308 using solder in a similar manner to copper post 324. After device 300 is over-molded with mold compound 306, support members of the lead frame are trimmed away to leave lead frame contacts 304, 305. These lead frame contacts allow device 300 to be mounted on a PCB, such as PCB 102 (FIG. 1) with aperture 310 facing away from the PCB.

IC die 320 is over-molded only on one side to form the bottom outer surface 307 of device 300. The top surface 309 of interconnect substrate 308 remains free of mold compound and becomes the opposite top outer surface of device 300. In this manner, aperture 310 remains free of mold compound.

FIG. 4 is a cross-sectional view of another example device 400 in which an interconnect substrate 408 includes an aperture 410 to expose an on-chip sensor 422 located in IC die 420 to the environment. In this example, IC die 420 is mounted in a flip-chip configuration. Interconnect substrate 408 is similar to interconnect substrate 308 (FIG. 3) with layers 411-414 of conductive and insulating material in which the conductive layers are patterned to form interconnect leads, such as interconnect lead 415.

An aperture 410 is fabricated in interconnect substrate 408 that extends from the top surface of interconnect substrate 408 to the opposite bottom surface of interconnect substrate 408. The location of aperture 410 is selected to align with the position of sensor element 422 when IC die 420 is coupled to interconnect substrate 408.

In this example, IC die 420 has copper posts formed on each bond pad of IC die 420. Post 424 is representative of these copper posts. The copper posts are fabricated using a known or later developed technique for forming posts on a silicon die. IC die 420 is coupled to interconnect substrate by soldering the copper posts to respective lead lines; for example, copper post 424 is soldered to interconnect lead line 415.

In this example, a continuous seal 430 is formed between the IC die 420 in the perimeter region around sensor element 422 and the top surface of interconnect substrate 408. In this example, seal 430 a low viscosity epoxy underfill installed to fill a gap between IC die 420 and interconnect substrate 408. The low viscosity epoxy may be installed using a syringe, for example. Low viscosity epoxy will be sucked into the gap between the IC die 420 and interconnect substrate 408 by capillary action. After curing, this seal prevents mold compound from entering aperture 410 when IC die 420 is over-molded with mold compound 406.

IC die 420 is over-molded only on one side to form the top outer surface 407 of device 400. The bottom surface 409 of interconnect substrate 408 remains free of mold compound and becomes the opposite bottom outer surface of device 400. In this manner, aperture 410 remains free of mold compound.

In this example, a set of contacts, such as contacts 404, 405 are formed in layer 414. Vias in lead layer 413 and via layer 412 couple contacts 404, 405 to respective lead lines in lead layer 411. Contacts 404, 405 allow device 400 to be mounted on a PCB, such as PCB 102 (FIG. 1) with aperture 410 facing towards the PCB. In this case, a hole aligned with aperture 410 may be needed in the PCB to allow sensor element 422 to be exposed to the environment.

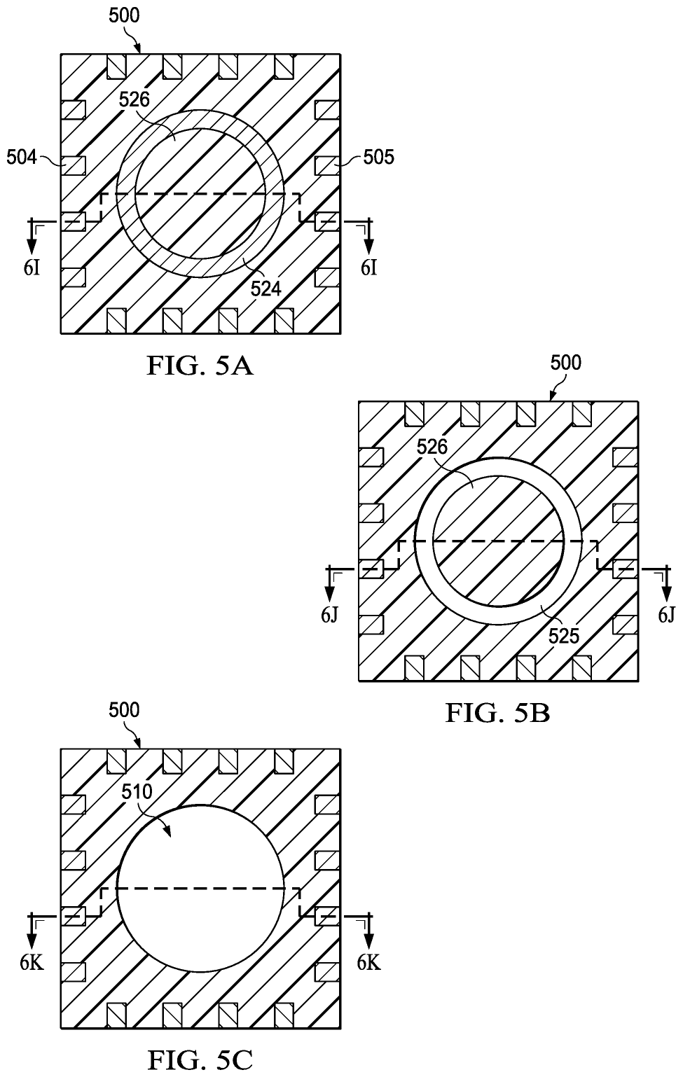

FIGS. 5A-5C are bottom views illustrating fabrication of an aperture 510 in an example interconnect substrate 500. Example interconnect substrate 500 is similar to interconnect substrate 108 (FIG. 1), interconnect substrate 308 (FIG. 3), and interconnect substrate 408 (FIG. 4).

FIG. 5A illustrates a set of copper contact pads, indicated generally at 504, 505, that are exposed on the bottom surface of interconnect substrate 500 that can be used to couple the interconnect substrate to another substrate, such as PCB 102 as illustrated in FIG.1. In this example, insulating layers of the interconnect substrate are fabricated with ABF.

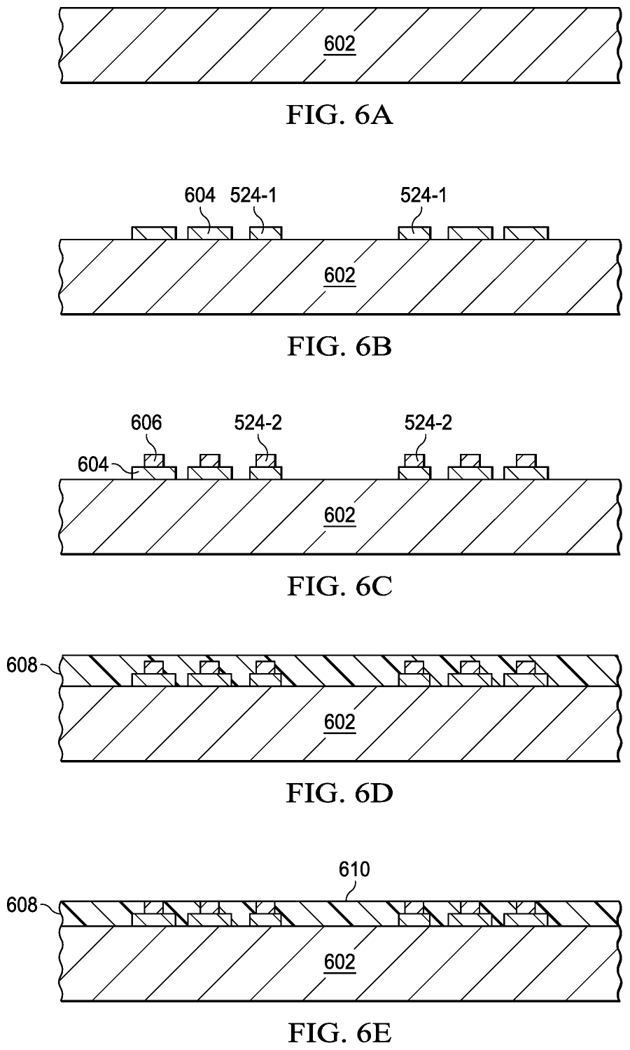

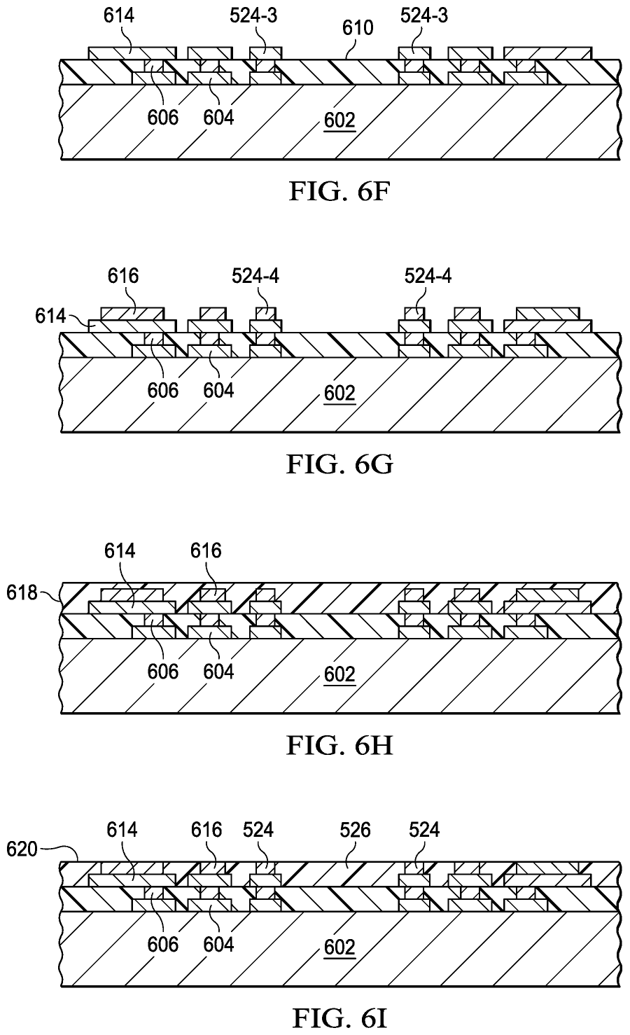

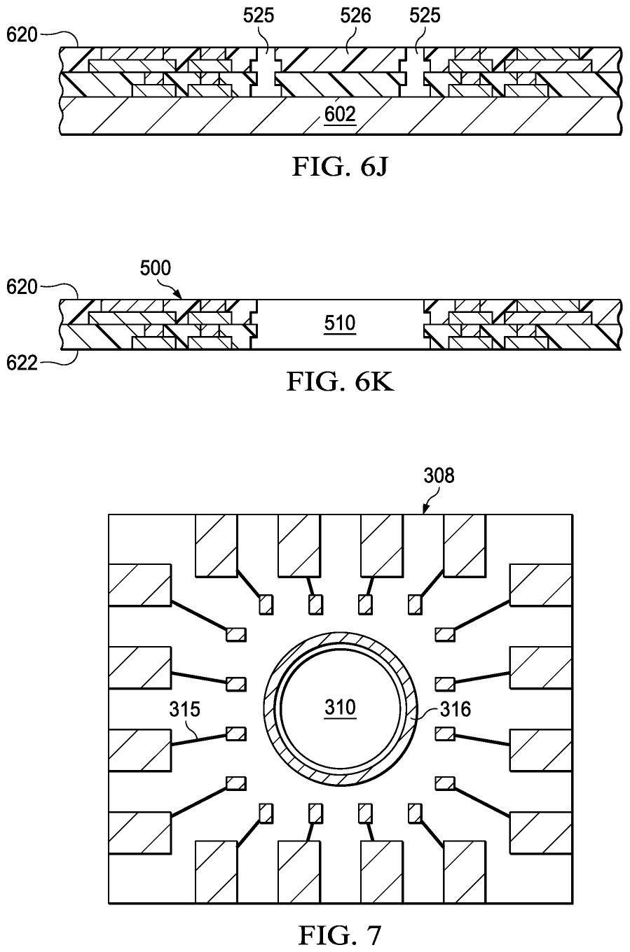

A copper cylinder 524 is fabricated as a stack of copper rings on each layer of interconnect substrate 500, as will be described in more detail with reference to FIGS. 6A-6K. While illustrated as a circular ring in this example, in other examples closed structure 524 may have other shapes, such as: oval, square, rectangular, etc. Residue element 526 is surrounded by copper cylinder 524.

FIG. 5B illustrates interconnect substrate 500 after removal of copper cylinder 524 using a etch process to form an empty cylindrical space 525 that surrounds residue element 526.

FIG. 5C illustrates interconnect substrate 500 after removal of residue element 526 to form aperture 510.

FIGS. 6A-6K illustrate fabrication of an example interconnect substrate 500 (FIG. 5C), which is similar to interconnect substrate 108 (FIG. 1), interconnect substrate 308 (FIG. 3), and interconnect substrate 408 (FIG. 4). Known or later developed techniques for fabricating a routable lead interconnect substrate can be used to fabricate an interconnect substrate. For example, see “Molded Interconnect Substate (MIS) Technology for Semiconductor Packages,” Michael M. Liu, 2020. A brief description of a technique to fabricate an interconnect substrate is described hereinbelow.

FIG. 6A illustrates a cross-sectional view of a metal carrier 602 on which the interconnect substrate is fabricated. In this example, an interconnect substrate for a single device is illustrated. Typically, a set of interconnect substrates will be fabricated at the same time arranged as a strip of substrates or a sheet of substrates. The substrates are then separated after fabrication of complete devices.

FIG. 6B illustrates a metal layer 604, such as copper, that is plated onto metal carrier 602, and then patterned using a lithographic process and etched to form a set of horizontal interconnect lead lines in various configurations to provide interconnects and bond pads for coupling to bond pads on an IC, for example. In this example, a closed ring 524-1 is provided to begin an outline of an aperture.

FIG. 6C illustrates a second metal layer 606, such as copper, that is plated, patterned, and etched to form a set of vertical vias for making vertical interconnects. For a single layer interconnect, the vias may be used for external contacts. For a multiple layer interconnects, the vias may connect interconnect leads on the first interconnect layer to respective interconnect leads on a second interconnect layer. In this example, a second closed ring 524-2 is fabricated on top of first ring 524-1.

FIG. 6D illustrates an insulating layer 608 that is formed over the first interconnect layer 604 and vias layer 606. In this example, insulating layer 608 is ABF. In another example, insulating layer 608 may be an epoxy molding compound, for example.

FIG. 6E illustrates a planarized top surface 610 that is produced by grinding insulating layer 608. In this manner, the tops of the vias and the top of ring 524-2 are exposed.

FIG. 6F illustrates a second interconnect layer 614, such as copper, that is plated onto planarized surface 610, and then patterned using a lithographic process and etched to form a second set of horizontal interconnect lead lines in various configurations. Interconnect leads in interconnect layer 614 can connect to tops of vias in via layer 606. In this example, a third closed ring 524-3 is fabricated on top of second ring 524-2.

FIG. 6G illustrates a second metal layer 606, such as copper, that is plated, patterned, and etched to form a set of vertical vias for making vertical interconnects. These vias may be used for external contacts. In this example, a fourth closed ring 524-4 is fabricated on top of third ring 524-3.

FIG. 6H illustrates a second insulating layer 618 that is formed over the second interconnect layer 614 and vias layer 616. In this example, insulating layer 618 is ABF. In another example insulating layer may be an epoxy molding compound, for example.

FIG. 6I illustrates a planarized top surface 620 that is produced by grinding insulating layer 618. In this manner, the tops of the vias are exposed. Likewise, the top of cylinder 524 is exposed. Cylinder 524 includes rings 524-1, 524-2, 524-3, 524-4 and encircles residue element 526.

FIG. 6J illustrates an empty cylindrical space 525 that surrounds residue element 526 after removal of copper cylinder 524 using an etch process. An etch mask is created on surface 620, then patterned to expose just the top of metal cylinder 524. Metal cylinder 524 is then removed by a complete metal etch process.

FIG. 6K illustrates a planarized bottom surface 622 that is opposite planarized top surface 620. Bottom surface 622 is formed by etching or grinding away the bulk of carrier 602 underneath the now molded/built-up interconnect substrate in order to expose the horizontal interconnects and die-attach pads. The exposed die-attach pads may be provided with a surface finish, such as NiPdAu, Cu+OSP, and/or pre-plated lead frame (PPF) configurations. Once carrier 602 is removed, residue element 526 is free and is removed to reveal aperture 510 that extends through upper surface 620 and bottom surface 622.

In this manner, a two-layer interconnect substrate having opposite planar surfaces is fabricated. Using the same process steps, aperture 510 is fabricated in the interconnect substrate. In other examples, additional interconnect layers may be fabricated in a similar manner. In another example, a single layer interconnect substrate may be fabricated in a similar manner.

FIG. 7 is a bottom view of an example interconnect substrate 308 (FIG. 3) illustrating continuous sealing ring 316 (see FIG. 3) in more detail. Sealing ring 316 is patterned and etched in the first interconnect layer 311 of interconnect substrate 308. As described for FIG. 3, sealing ring 316 is configured to align with a matching copper ring that is fabricated on an IC, such as copper ring 325 (FIG. 3) on IC 320 (FIG. 3). In this example, copper ring 316 and copper ring 325 (FIG. 3) are circular in shape. In another example, a different shape may be fabricated, such as oval, square, rectangular, etc.

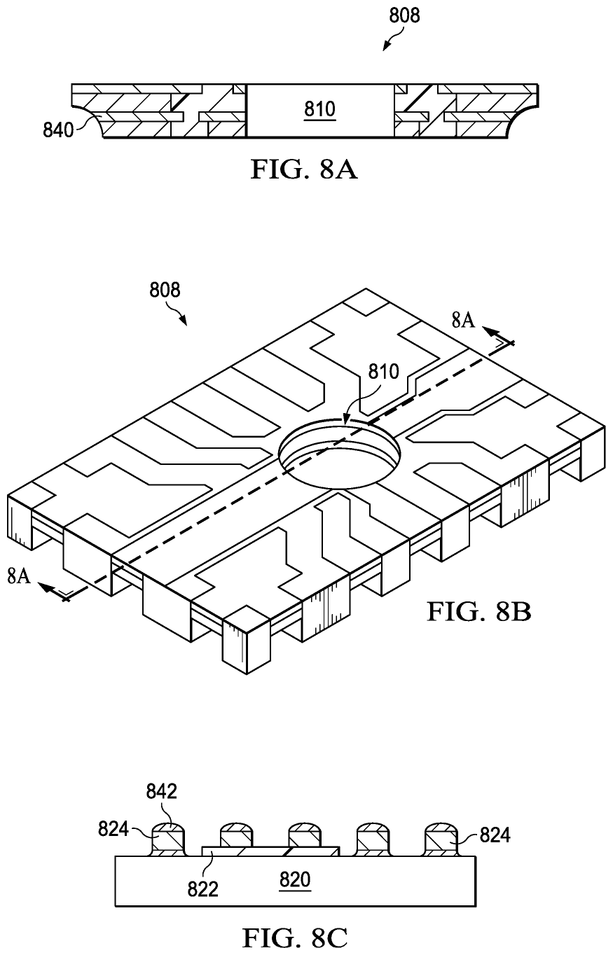

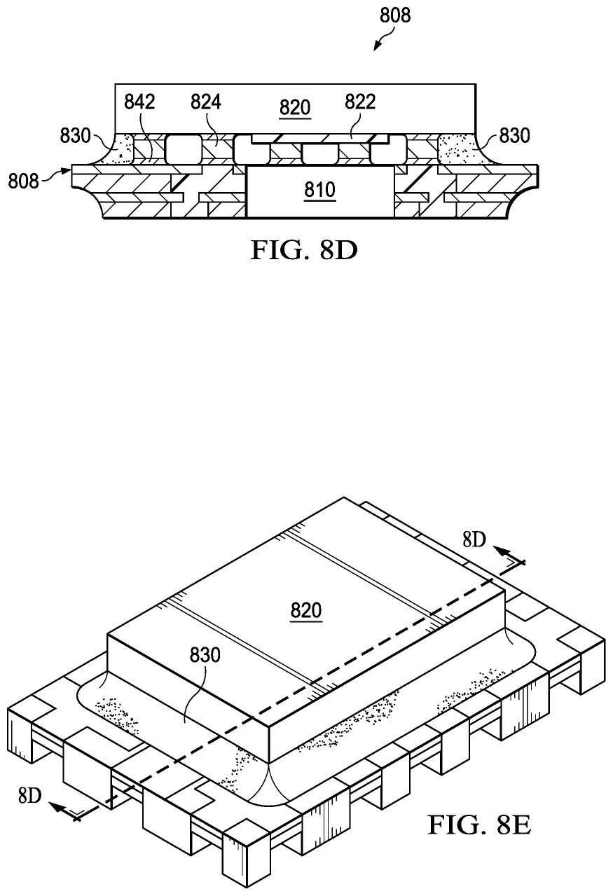

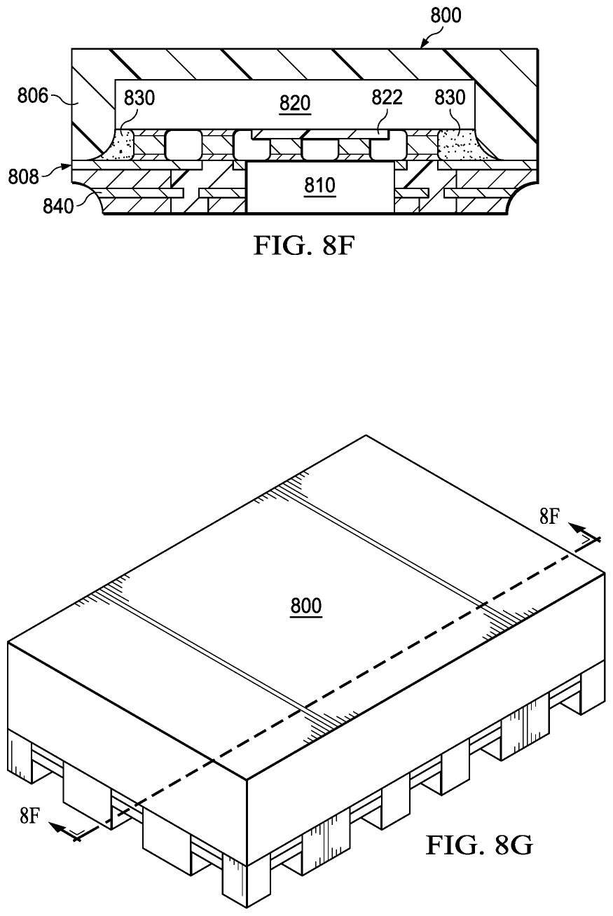

FIGS. 8A-8G illustrate assembly and encapsulation of an example device 800 with an aperture 810 to expose an on-chip sensor 822. In this example, interconnect substrate 808 is similar to interconnect substrate 408 (FIG. 4). Interconnect substrate includes a region 840 on each perimeter side that is etched to create a recess that is then plated with a conductive material, such as gold, to create a solder wettable flank region for each contact pad.

FIG. 8A is a cross-sectional view and FIG. 8B is an isometric view of an example interconnect substrate 808 that includes an aperture 810 that is fabricated as illustrated in FIGS. 6A-6K.

FIG. 8C is a cross-sectional view of an example IC die 820 that has an on-chip sensor 822. IC die 820 includes raised copper posts 824 that are topped with a solder paste to facilitate soldering IC 820 to interconnect substrate 808.

FIG. 8D is a cross-sectional view and FIG. 8E is an isometric view of an example IC 820 after it is soldered to example interconnect substrate 808 using a known or later developed technique.

In this example, a continuous seal 830 of sealing compound is installed in a perimeter region of IC 820 around sensor element 822 between the bottom surface of IC 820 and the top surface of interconnect 808. In this example, seal 830 a low viscosity epoxy underfill installed to fill a gap between IC die 820 and interconnect substrate 808. This seal prevents mold compound from entering aperture 810 when IC die 820 is over-molded with mold compound 806.

FIG. 8F is a cross-sectional view and FIG. 8G is an isometric view of completed example sensor device 800. Mold compound 806 is over-molded over only the top side of IC die 820 and portions of the top surface of interconnect substrate 808. Mold compound 806 forms a top surface of sensor device 800, while the bottom surface of interconnect substrate 808 forms the opposite bottom surface of sensor device 800. Continuous seal 830 around the perimeter region of IC die 820 around sensor element 822 prevents mold compound 806 from entering aperture 810 during the over-molding process. In this manner, aperture 810 penetrates the outer surface of device 800 after over-molding is performed.

In this manner, a sensor device is fabricated as a quad flat no-lead (QFN) package with an IC die mounted in a flip-chip configuration that has a downward facing aperture for sensor element. In this example, if the sensor device is mounted on a PCB, a hole would be provided in the PCB to provide access for the on-chip sensor to the environment around the sensor device.

In another example, a similar process may be used to package an IC die with an on-chip sensor element in an upward facing configuration using an auxiliary lead frame, such as a lead frame with contacts 304, 305 (FIG. 3).

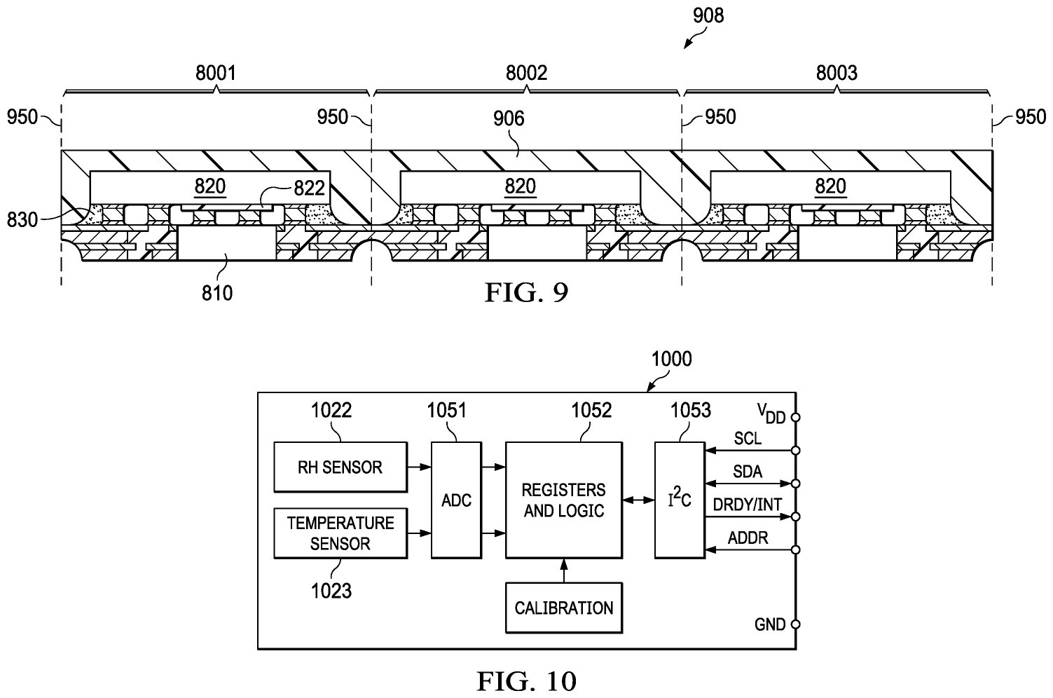

FIG. 9 is a cross sectional view of a strip 908 of example interconnect substrates illustrating several encapsulated devices 9001, 9002, 9003 prior to singulation. In this example, the individual IC die 820 are mounted to the interconnect substrates strip 908 using a known or later developed die attach technique.

In this example, a continuous seal of sealing compound 830 is installed in a perimeter region of each IC 820 around sensor element 822 between the bottom surface of IC 820 and the top surface of interconnect strip 908. In this example, the seal is a low viscosity epoxy underfill installed to fill a gap between each IC die 820 and interconnect substrate 908. This seal prevents mold compound from entering aperture 810 when IC die 820 is over-molded with mold compound 806.

The complete strip is then over-molded with molding compound 906. Aperture region 810 remains free of mold compound due to the seal in the perimeter region of each IC die 820.

After being over-molded, the strip is then singulated by sawing, or by other known or later developed singulation techniques.

FIG. 10 is a schematic of an example sensor device 1000 that includes an on-chip sensor. In this example, sensor device 1000 includes an on-chip relative humidity (RH) sensor 1022 and an on-chip temperature sensor. Relative humidity sensor 1022 needs to be exposed to the environment through an aperture in the sensor device's package. An aperture is provided via an interconnect substrate, such as example interconnect substrate 308 (FIG. 3) or interconnect substrate 408 (FIG. 4). In this example, analog to digital converter (ADC) 1051 converts analog signal samples from RH sensor 1022 and temperature sensor 1023 to digital data samples which are then stored by logic 1052 in local registers. In this example, an inter-integrated circuit (I2C) interface is configured to allow external devices that are coupled to the contact pads of device 1000 to access the sensor data samples.

### Other Embodiments

In described examples, a sensor device has an IC die that is sealed to an interconnect substrate using an epoxy underfill to fill a gap between the IC die and the interconnect substrate. In another described example, a ring formed on an IC die is used to seal a gap between the IC die and an interconnect substrate. In each case, the IC die is mounted in a flip-chip configuration with the sensor element facing down. Either sealing configuration may be used with an auxiliary lead frame to so that the sensor element can be facing up in the encapsulated package.

In described examples, a sensor device is provided with a round aperture to allow an on-chip sensor access to a surrounding environment. In other examples, the aperture may be a different shape, such as oval, square, rectangular, etc.

In described examples, an aperture is defined by a closed metallic shape that has a central core that is filled with dielectric. After etching away the closed metallic shape the dielectric core is removed. In another example, the closed metallic shape may be solid metal, so that after the metal shape is etched away the aperture is revealed.

In described examples, an IC die with an on-chip sensor element is described. In other examples, a IC die that has an on-chip actuator element or other type of on-chip element that must interact with an environment outside of the chip package. For example, such an on-chip element may be an ultrasonic transducer, a laser emitter, a micro-electromechanical (MEMS) actuator, a deformable mirror, etc.

In described examples, the interconnect substrate is an RLF, also known as a molded interconnect substrate, that is fabricated using a series of additive processing steps to form an interconnect substrate having one or more conductive layers that are patterned into routed leads and covered with insulating material. In another example, an interconnect substrate may be fabricated using other known or later developed techniques, such as a multilayer ceramic interconnect substrate, a silicon-based interconnect substrate, etc.

In described examples, an interconnect substrate is fabricated using copper plating and ABF insulating material. In other examples, a different combination of conductive material and insulating material may be used. For example, epoxy insulation material may be used.

In described example, an aperture is formed in an example interconnect substrate using the same process steps used to form the interconnect leads. In another example, an aperture may be formed in an example substrate after the substrate is complete by machining a hole, such as by drilling, laser cutting, stamping, etc.

In described examples, the surface of the interconnect substrate is ground flat to form a planar surface. In another example, grinding may not be required as long as the surface is flat enough to allow a continuous seal to be formed around the perimeter of the aperture to prevent mold compound from entering the aperture during the over-mold process.

In described examples, a quad flat no-lead package is formed. In other examples, various types of packages may be formed in which an aperture for an on-chip sensor element penetrates in interconnect substrate that forms an outer surface of the package, such as a quad flat pack, dual flat pack, dual flat no-lead, dual inline, etc.

In this description, the term “couple” and derivatives thereof mean an indirect, direct, optical, and/or wireless electrical connection. Thus, if a first device couples to a second device, that connection may be through a direct electrical connection, through an indirect electrical connection via other devices and connections, through an optical signal connection, etc.

Modifications are possible in the described embodiments, and other embodiments are possible, within the scope of the claims.

What is claimed is:

1. A device, comprising:
an interconnect substrate having a first surface and an opposite second surface, the interconnect substrate having an aperture extending through the first surface and the second surface;
an integrated circuit (IC) die having a first side and an opposite second side, the IC having an on-chip element surrounded by a perimeter region on the first side of the IC, the first side of the IC die coupled to the second surface if the interconnect substrate with the on-chip element exposed in the aperture;
encapsulation material covering the second side of the IC die and a portion of the second surface of the interconnect substrate, the encapsulation material having an exposed surface; and
the device having a first surface and an opposite second surface, the first surface of the device being the first surface of the interconnect substrate and the second surface of the device being a portion of the exposed surface of the encapsulation material, such that the aperture penetrates the first surface of the device.

2. The device of claim 1, further comprising a sealing material in the perimeter region around the on-chip element between the first surface of the IC die and the second surface of the interconnect substrate.

3. The device of claim 2, wherein the sealing material is a metal ring.

4. The device of claim 2, wherein the sealing material is cured epoxy.

5. The device of claim 1, further comprising lead frame contacts each having a first surface and an opposite second surface, the first surface of the lead frame contacts coupled to the second surface of the interconnect substrate, wherein the second surface of the lead frame contacts is a portion of the second surface of the device.

6. The device of claim 5, further comprising a sealing material in the perimeter region of the on-chip element between the first surface of the IC die and the second surface of the interconnect substrate.

7. The device of claim 1, wherein the on-chip element is an on-chip sensor element.

8. The device of claim 1, wherein the on-chip element is an on-chip actuator element.

9. The device of claim 6, wherein the device is a quad flat no-lead (QFN) package, and wherein the aperture penetrates a top surface of the QFN package.

10. The device of claim 1, wherein the first surface of the interconnect substrate and the second surface of the interconnect substrate are planar surfaces.

11. A method of fabricating a device, the method comprising:
fabricating an interconnect substrate having a first surface and an opposite second surface, the interconnect substrate having contact pads on the second surface;
forming an aperture in the interconnect substrate extending through the first surface and the second surface;
mounting an integrated circuit (IC) die on the second surface of the interconnect substrate such that an on-chip element on the IC die is exposed in the aperture and bond pads on the IC die are coupled to a portion of the contact pads on the second surface of the interconnect substrate;
sealing a perimeter region of the IC die around the on-chip element to the second surface of the interconnect substrate; and
over-molding the IC die and a portion of the second surface of the interconnect substrate with a mold compound while keeping the first surface of the interconnect substrate and the aperture free of the mold compound.

12. The method of claim 11, wherein fabricating an interconnect substrate comprises:
etching a first layer of metal on a support substrate to form leads with contact pads and a first closed structure;
etching a second layer of metal overlying the first layer of metal to form vias and a second closed structure, wherein the second closed structure is aligned with the first closed structure to form a metallic closed structure;
covering the first and second layer of metal with an insulating material;
creating the first surface of the interconnect substrate by removing a portion of the insulating material; and
creating the second surface of the interconnect substrate by removing the support substrate to expose a surface of the contact pads and a surface of a portion of the insulating material opposite the first surface of the interconnect substrate.

13. The method of claim 12, wherein forming an aperture comprises:
creating an etch mask on the first surface of the interconnect substrate that exposes a portion of the metallic closed structure;
etching the metallic closed structure completely away to create a closed space surrounding a residue element; and
removing the residue element.

14. The method of claim 11, wherein forming an aperture comprising machining a hole through the interconnect substrate.

15. The method of claim 11, wherein sealing the perimeter region of the IC die to the second surface comprises inserting an underfill material between the perimeter region of the IC die and the second surface of the interconnect substrate.

16. The method of claim 11, wherein sealing a perimeter region of the IC die to the second surface comprises soldering a closed metal ring on the IC die to the interconnect substrate.

17. The method of claim 11, further comprising:
coupling lead frame contacts on a lead frame to another portion of the contact pads on the interconnect substrate prior to over-molding the IC die with the mold compound; and
exposing a surface of the lead frame contacts after over-molding the IC die, the lead frame, and a portion of the first surface of the interconnect substrate.

18. The method of claim 11, wherein multiple interconnect substrates are fabricated and over-molded in parallel to form multiple devices, further comprising separating the multiple devices after they are over-molded.

19. A method of fabricating a device, the method comprising:
etching a first layer of metal on a support substrate to form leads with contact pads and a first closed structure;
etching a second layer of metal overlying the first layer of metal to form vias and a second closed structure, wherein the second closed structure is aligned with the first closed structure to form a metallic closed structure;
covering the first and second layer of metal with an insulating material;
creating a first surface of an interconnect substrate by removing a portion of the insulating material;
creating an etch mask on the first surface of the interconnect substrate that exposes a portion of the metallic closed structure;
etching the metallic closed structure completely away to create a closed space surrounding a residue element;
creating a second surface of the interconnect substrate by removing the support substrate to expose a surface of the contact pads and a surface of a portion of the insulating material opposite the first surface of the interconnect substrate; and
removing the residue element to form an aperture that extends through the interconnect substrate from the first surface to the opposite second surface.

20. The method of claim 19, further comprising:
mounting an integrated circuit (IC) die on the second surface of the interconnect substrate such that an on-chip element on the IC die is exposed in the aperture and bond pads on the IC die are coupled to a portion of the contact pads on the second surface of the interconnect substrate;
sealing a perimeter region of the IC die around the on-chip element to the second surface of the interconnect substrate; and
over-molding the IC die and a portion of the second surface of the interconnect substrate with a mold compound while keeping the first surface of the interconnect substrate and the aperture free of the mold compound.
